(19) United States
(12) Patent Application Publication
(10) Pub. No.: US 2013/0140545 A1
(43) Pub. Date: Jun. 6, 2013

(54) MOISTURE ABSORPTION FILLING MATERIAL FOR ORGANIC LIGHT EMITTING DEVICE, METHOD FOR PREPARING THE SAME, AND ORGANIC LIGHTING EMITTING DEVICE INCLUDING THE SAME

(71) Applicants: Mi Sun KIM, Uiwang-si (KR); Ji Yeon LEE, Uiwang-si (KR); Kil Sung LEE, Uiwang-si (KR); Min Haeng CHO, Uiwang-si (KR); Kie Hyun NAM, Seongnam-si (KR); Jung Woo MOON, Suwon-si (KR); Ji Sil LEE, Uijeongbu-si (KR)

(72) Inventors: Mi Sun KIM, Uiwang-si (KR); Ji Yeon LEE, Uiwang-si (KR); Kil Sung LEE, Uiwang-si (KR); Min Haeng CHO, Uiwang-si (KR); Kie Hyun NAM, Seongnam-si (KR); Jung Woo MOON, Suwon-si (KR); Ji Sil LEE, Uijeongbu-si (KR)

(21) Appl. No.: 13/752,696

(22) Filed: Jan. 29, 2013

Related U.S. Application Data
(63) Continuation of application No. PCT/KR2010/009265, filed on Dec. 23, 2010.

(30) Foreign Application Priority Data
Jul. 30, 2010 (KR) 10-2010-0074224
Dec. 22, 2010 (KR) 10-2010-0132897

(51) Int. Cl. H01L 51/00; C08K 3/22; H01L 51/52; B32B 5/28

(52) U.S. Cl. CPC C08K 3/22; H01L 51/524
USPC 257/40; 442/59

(57) ABSTRACT

A moisture absorption filling material for an organic light-emitting device may include a fibrous web structure including an assembly of fibers, the fibers including a binder resin and hygroscopic particles, the hygroscopic particles being secured into the fibers. A method of preparing a moisture absorption filling material for an organic light-emitting device may include electrospinning a mixture including about 10 wt % to about 60 wt % of hygroscopic particles and about 40 wt % to about 90 wt % of a binder.

### CROSS-REFERENCE TO RELATED APPLICATIONS

This application is a continuation of pending International Application No. PCT/KR2010/009265, entitled “Moisture Absorption Filling Material for Organic Light Emitting Device, Method for Preparing the Same, and Organic Lighting Emitting Device Including the Same,” which was filed on Dec. 23, 2010, the entire contents of which are hereby incorporated by reference.

This application also claims priority under 35 U.S.C. §119 to Korean Patent Application No. 10-2010-0074224, filed on Jul. 30, 2010, in the Korean Intellectual Property Office, the entire contents of which are hereby incorporated by reference.

This application also claims priority under 35 U.S.C. §119 to Korean Patent Application No. 10-2010-0132897, filed on Dec. 22, 2010, in the Korean Intellectual Property Office, the entire contents of which are hereby incorporated by reference.

### BACKGROUND

1. Field

Embodiments relate to a moisture absorption filling material for an organic light-emitting device, a method of preparing the same, and an organic light-emitting device including the same.

2. Description of the Related Art

An organic light-emitting device (OLED) may be a self light emitting device having a structure wherein a thin layer (e.g., an organic electroluminescent layer including a fluorescent organic compound), may be interposed between a pair of electrodes constituting positive and negative electrodes. The OLED may emit fluorescent or phosphorescent light upon inactivation of excitons generated in the thin layer through recombination of holes and electrons injected into the thin layer.

### SUMMARY

Embodiments are directed to a moisture absorption filling material for an organic light-emitting device, the material may include a fibrous web structure including an assembly of fibers, the fibers may include a binder resin and hygroscopic particles, and the hygroscopic particles may be secured into the fibers.

The fibers may have an average diameter of about 0.1 μm to about 200 μm.

The moisture absorption filling material may have a porosity of about 5% to about 95% and may be formed with pores having an average diameter of about 0.1 μm to about 100 μm.

The hygroscopic particles may include a hygroscopic material particle made of a hygroscopic material, a surface-treated hygroscopic material particle obtained by surface treatment of the hygroscopic material with a polymer resin, or a mixture of the hygroscopic material particle and the surface-treated hygroscopic material particle.

The hygroscopic material may include at least one selected from the group of a molecular sieve zeolite, a silica gel, a carbonate, a clay, a metal oxide, a metal hydroxide, an alkali earth metal oxide, a sulfate, a metal halide, a perchlorate, an organic metal compound, and an organic/inorganic hybrid material that physically or chemically adsorbs moisture.

The hygroscopic particles may include the surface-treated hygroscopic material particle obtained by surface treatment of the hygroscopic material with the polymer resin, and the polymer resin may be continuously or discontinuously secured to a surface of the hygroscopic material.

The polymer resin may be secured to the surface of the hygroscopic material in a ratio of about 5% to about 100% of a surface area of the hygroscopic material.

The polymer resin may be secured to the surface of the hygroscopic material by forming a polymer resin coating layer on the hygroscopic material, or by disposing fine projection type polymer resin grains on the hygroscopic material.

The hygroscopic material may have an average particle diameter ranging from about 0.01 μm to about 200 μm.

The binder may include at least one selected from the group of a polyvinyl acetate resin, a polyvinyl pyrrolidone resin, a polyester resin, a polyolefin resin, a (meth)acrylate resin, a polycarbonate resin, an acrylonitrile resin, a cellulose acetate resin, an epoxy resin, a phenoxy resin, a siloxane resin, a sulfone resin, a polyamide resin, a polyurethane resin, a polyvinyl resin, a urethane acrylate resin, and a fluoride resin.

The binder may have a glass transition temperature of about −60° C. to about 170° C.

The binder may have a glass transition temperature of about −60° C. to about 80° C.

The fibers may include about 40 wt % to about 90 wt % of the binder and about 10 wt % to about 60 wt % of the hygroscopic particles.

The moisture absorption filling material may have a thickness of about 5 μm to about 500 μm.

The moisture absorption filling material may further include a coating layer.

The moisture absorption filling material may further include a sheet having pores, and the sheet may contact at least one side of the fibrous web structure.

The sheet may have a porosity of about 5% to about 95%.

The sheet may be a moisture permeable sheet, and may include a non-woven fabric, a woven fabric, a latex sheet, or a combination thereof

The non-woven fabric may include at least one selected from the group of a polyvinyl acetate resin, a polyvinyl pyrrolidone resin, a polyester resin, a polyolefin resin, a (meth)acrylate resin, a polycarbonate resin, an acrylonitrile resin, a cellulose acetate resin, an epoxy resin, a phenoxy resin, a siloxane resin, a sulfone resin, a polyamide resin, a polyurethane resin, a polyvinyl resin, a urethane acrylate resin, and a fluoride resin, the woven fabric may include at least one selected from the group of a polyvinyl acetate resin, a polyvinyl pyrrolidone resin, a polyester resin, a polyolefin resin, a (meth)acrylate resin, a polycarbonate resin, an acrylonitrile resin, a cellulose acetate resin, an epoxy resin, a phenoxy resin, a siloxane resin, a sulfone resin, a polyamide resin, a polyurethane resin, a polyvinyl resin, a urethane acrylate resin, and a fluoride resin, and the latex sheet may include at least one selected from the group of a polyurethane, a polybutadiene, a nitrile rubber, an acryl rubber, and a polysiloxane.

The sheet may have a thickness of about 0.5 μm to about 500 μm.

The sheet may include a coating layer formed thereon.

The moisture absorption filling material may have a structure in which the fibrous web structure, the sheet having pores, and the coating layer are sequentially stacked.

The moisture absorption filling material may have a surface roughness (Ra) of about 50 μm or less.

Embodiments are also directed to a method of preparing a moisture absorption filling material for an organic light-emitting device, the method may include electrospinning a mixture including about 10 wt % to about 60 wt % of hygroscopic particles and about 40 wt % to about 90 wt % of a binder.

The mixture may further include a solvent.

The mixture may be applied to at least one side of a sheet having pores by electrospinning.

The mixture may be directly applied to a sealing cap by electrospinning, and the sealing cap may be coupled to a substrate and may accommodate an organic electroluminescent unit.

The method may further include preparing a moisture absorption filling material by electrospinning the mixture, and stacking a sheet having pores on at least one side of the moisture absorption filling material.

The sheet may be adhesively attached to the at least one side of the moisture absorption filling material.

The electrospinning may be performed at an interelectrode distance of about 5 cm to about 40 cm and at a voltage of about 5 kV to about 45 kV.

Upon the electrospinning, an electrospinning zone may be maintained at a temperature ranging from room temperature to about 80° C.

Embodiments are also directed to an organic light-emitting device including the moisture absorption filling material.

Embodiments are also directed to an organic light-emitting device which may include a substrate, an organic electroluminescent unit on one side of the substrate, the organic electroluminescent unit including a first electrode, an organic light emitting layer, and a second electrode, a sealing cap coupled to the substrate and accommodating the organic electroluminescent unit therein, and a drying mechanism within the sealing cap, the drying mechanism being the moisture absorption filling material.

### BRIEF DESCRIPTION OF DRAWINGS

Features will become apparent to those of skill in the art by describing in detail exemplary embodiments with reference to the attached drawings in which:

FIG. 1 illustrates a schematic sectional view of a sealing structure of an organic light-emitting device.

FIG. 2 illustrates a schematic view of a moisture absorption filling material for an organic light-emitting device according to an embodiment.

FIG. 3 illustrates an enlarged view of Circle A in FIG. 2.

FIGS. 4(a), 4(b), and 4(c) illustrate schematic sectional views of a hygroscopic particle obtained by surface treatment of a hygroscopic material with a polymer resin.

FIG. 5 illustrates a schematic view of the moisture absorption filling material to which hygroscopic particles having fine projection type grains are applied.

FIGS. 6(a) and 6(b) illustrate schematic sectional views of a sheet having pores.

FIGS. 7(a), 7(b), 7(c), 7(d), and 7(e) illustrate schematic sectional views of a moisture absorption filling material for an organic light-emitting device according to an embodiment.

FIG. 8 illustrates a schematic sectional view of an organic EL device according to an embodiment.

FIG. 9 illustrates a schematic sectional view of an organic EL device according to an embodiment.

FIG. 10 illustrates an optical microscope image of a moisture absorption filling material prepared in Example 1.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will be understood that when a layer is referred to as being “between” two layers, it can be the only layer between the two layers, or one or more intervening layers may also be present. Like reference numerals refer to like elements throughout.

Moisture absorption filling material for organic light-emitting device

A moisture absorption filling material for organic light-emitting devices according to an embodiment may have a fibrous web structure comprised of an assembly of a plurality of fibers. The fibers may comprise a binder resin and hygroscopic particles, and the hygroscopic particles may be secured into the fibers.

FIG. 2 illustrates a schematic view of a moisture absorption filling material for an organic light-emitting device according to an embodiment. As shown in FIG. 2, the moisture absorption filling material 100 according to this embodiment has a fibrous web structure in which fibers 10 are entangled such that pores are formed between the fibers 10, thereby providing porosity. The fibers may be regularly or irregularly entangled with each other.

The fibers may have an average diameter from about 0.1 μm to about 200 μm, from about 1 μm to about 100 μm, or from about 3 μm to about 70 μm, and may have a length from about 0.1 mm to about 100 mm. Within this range of the average diameter of the fibers, the sheet may secure hygroscopic particles. The fibers in a diameter range of several micrometers may impart high mechanical strength to a fibrous structure and may form uniform pores to substantially prevent and/or significantly reduce deterioration in moisture absorption efficiency due to the binder.

In addition, the moisture absorption filling material having the fibrous web structure may have a porosity from about 5% to about 95%, or about 10% to about 80%, and may be formed with pores having an average diameter ranging from about 0.1 μm to about 100 μm. The pores in the fibers (e.g., between the fibers) may allow moisture and gas (e.g., oxygen) to efficiently pass therethrough to react with the hygroscopic particles. Further, within this range of porosity, the fibers may provide excellent hygroscopicity and may serve as a buffering layer between a moisture absorbing layer and the light emitting device. The moisture absorption filling material for an organic light-emitting device may have a thickness from about 5 μm to about 500 μm.

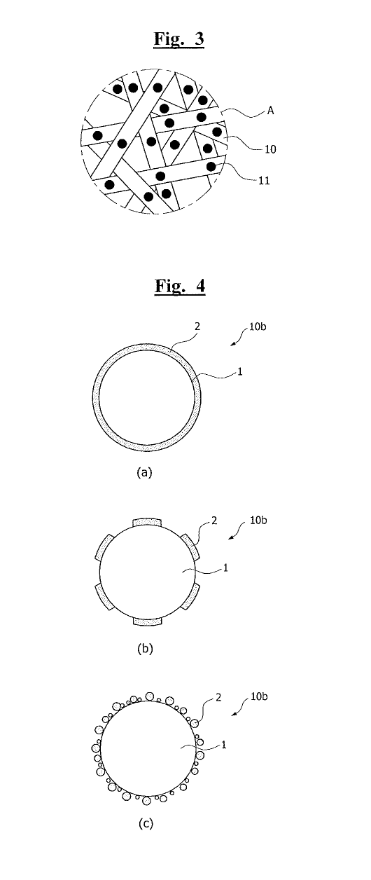

FIG. 3 illustrates an enlarged view of Circle A of FIG. 2. As illustrated in FIG. 3, hygroscopic particles 10a may be secured into (e.g., embedded in) the fibers 10 arranged to provide the fibrous web structure. In an embodiment, the moisture absorption filling material for organic light-emitting devices may further include a coating layer.

Hygroscopic Particles

According to an embodiment, the hygroscopic particles may have an average diameter of about 0.01 μm to about 200 μm. The sizes of the hygroscopic particles may be smaller than or equal to the diameters of the fibers, and thus the hygroscopic particles may be secured into the fibers.

The hygroscopic particles may include a hygroscopic material, hygroscopic particles obtained by surface treatment of the hygroscopic material with a polymer resin, mixtures thereof, or the like. That is the hygroscopic particles may be hygroscopic particles including a surface treatment, hygroscopic particles without a surface treatment, or a mixture thereof.

The hygroscopic material may include molecular sieve zeolite, silica gel, carbonates, clay, metal oxides, metal hydroxides, alkali earth metal oxides, sulfates, metal halides, perchlorates, organic metal compounds, organic/inorganic hybrid materials capable of physically or chemically absorbing moisture, and the like. These materials may be used alone or in combination thereof.

Examples of the carbonates may include sodium carbonate, sodium bicarbonate, and the like. Examples of the metal oxides may include lithium oxide (Li₂O), sodium oxide (Na₂O), potassium oxide (K₂O), and the like. Examples of the alkali earth metal oxides may include barium oxide (BaO), calcium oxide (CaO), magnesium oxide (MgO), and the like. Examples of the metal hydroxides may include calcium hydroxide, potassium hydroxide, and the like. Examples of the sulfates may include lithium sulfate (Li₂SO₄), sodium sulfate (Na₂SO₄), calcium sulfate (CaSO₄), magnesium sulfate (MgSO₄), cobalt sulfate (CoSO₄), gallium sulfate (Ga2(SO₄)₃), titanium sulfate (Ti(SO₄)₂), nickel sulfate (NiSO₄), and the like. Examples of the metal halides may include calcium chloride (CaCl₂), magnesium chloride (MgCl₂), strontium chloride (SrCl₂), yttrium chloride (YCl₂), copper chloride (CuCl₂), cesium fluoride (CsF), tantalum fluoride (TaF₅), niobium fluoride (NbF₅), lithium bromide (LiBr), calcium bromide (CaBr₃), cerium bromide (CeBr₄), selenium bromide (SeBr₂), vanadium bromide (VBr₂), magnesium bromide (MgBr₂), barium iodide (BaI₂), magnesium iodide (MgI₂), and the like. Examples of the perchlorates may include barium perchlorate (Ba(ClO₄)₂), magnesium perchlorate (Mg(ClO₄)₂), and the like. In an implementation, the hygroscopic material may be comprised of metal oxides, metal hydroxides, alkali earth metal oxides, sulfates, or combinations thereof.

The hygroscopic material may have an average particle diameter of about 0.01 μm to about 200 μm. In an implementation, the hygroscopic material may have an average particle diameter ranging from about 0.05 μm to about 100 μm, about 0.1 μm to about 50 μm, or about 0.1 μm to about 25 μm. Within this range, the hygroscopic material may allow easy handling without significantly deteriorating moisture absorption efficiency.

In an embodiment, the hygroscopic particles may be composed of the hygroscopic material itself as described above, hygroscopic particles obtained by surface treatment of the hygroscopic material with a polymer resin, or a combination of hygroscopic particles composed of the hygroscopic material itself and hygroscopic particles obtained by surface treatment of the hygroscopic material with a polymer resin. The hygroscopic particles obtained by surface treatment of the hygroscopic material with a polymer resin may be surface treated prior to being mixed with the binder resin.

FIGS. 4(a), 4(b), and 4(c) illustrate schematic sectional views of a hygroscopic particle 10b obtained by surface treatment of the hygroscopic material with a polymer resin. As illustrated in these figures, the hygroscopic particle 10b obtained by surface treatment of the hygroscopic material with the polymer resin may include a hygroscopic material 1 and a polymer resin 2 continuously or discontinuously formed on the surface of the hygroscopic material. In this way, the polymer resin 2 may be securely fixed on the surface of the hygroscopic material 1, and thus dark spots may not occur in the event that the hygroscopic particles 10b contact the device.

In an embodiment, the polymer resin 2 may be secured to the surface of the hygroscopic material 1 by coating. The polymer resin may be secured to the surface of the hygroscopic material by coating the polymer resin on an entire (e.g., overall) or a partial surface of the hygroscopic material. The polymer resin may include a polymer of a crosslinking monomer, a polymer of vinyl monomers, or a copolymer of a crosslinking monomer and a vinyl monomer. The polymer of the crosslinking monomer may be a polymer of at least one crosslinking monomer, and the polymer of the vinyl monomer may be a polymer of at least one vinyl monomer. In addition, the copolymer of the crosslinking monomer and the vinyl monomer may be a copolymer of at least one crosslinking monomer and at least one vinyl monomer. These polymers may be used alone or in combination thereof.

In an embodiment, the polymer resin may have a glass transition temperature of about −60° C. to about 170° C. Within this range, the polymer resin may be substantially prevented from agglomerating (and/or agglomeration may be significantly reduced) to secure the polymer resin to the surface of the hygroscopic material. In an embodiment, when the polymer resin 2 is secured to the surface of the hygroscopic material 1 by coating, the polymer resin may be secured in a ratio of about 5% to about 100% of the surface area of the hygroscopic material.

Examples of the crosslinking monomer may include divinylbenzene, divinylsulfone, allyl(meth)acrylate, diallyl phthalate, diallylacrylamide, triallyl(iso)cyanurate, triallyl trimellitate, ethylene glycol di(meth)acrylate, propylene glycol di(meth)acrylate, 1,4-butandiol di(meth)acrylate, 1,6-hexanediol di(meth)acrylate, 1,9-nonanediol di(meth)acrylate, pentaerythritol tetra(meth)acrylate, pentaerythritol tri(meth)acrylate, pentaerythritol di(meta)acrylate, trimethylolpropane tri(meth)acrylate, ditrimethoxypropane tetra(meth)acrylate, tetramethylolpropane tetra(meth)acrylate, dipentaerythritol hexa(meth)acrylate, dipentaerythritol penta(meth)acrylate, glycerol tri(meth)acrylate, and the like. These monomers may be used alone or in combination thereof.

The vinyl monomer may permit radical polymerization. Examples of the vinyl monomer may include aromatic vinyl monomers such as styrene, ethyl vinyl benzene, a-methylstyrene, m-chloromethylstyrene, and the like; (meth)acrylate monomers such as methyl(meth)acrylate, ethyl(meth)acrylate, propyl(meth)acrylate, n-butyl(meth)acrylate, isobutyl(meth)acrylate, t-butyl(meth)acrylate, 2-ethylhexyl(meth)acrylate, n-octyl(meth)acrylate, lauryl(meth)acrylate, stearyl(meth)acrylate, and the like; vinyl acetates, vinyl propionates, vinyl butyrate, vinyl ether, allyl butyl ether, and the like.

As illustrated in FIG. 4(a), the polymer resin 2 may be continuously formed on the surface of the hygroscopic material 1. When the polymer resin 2 is continuously secured to the surface of the hygroscopic material 1, the polymer resin 2 may completely surround the surface of the hygroscopic material 1.

As illustrated in FIGS. 4(b) and 4(c), the polymer resin 2 may be discontinuously formed on the surface of the hygroscopic material 1. When the polymer resin 2 is discontinuously secured to the surface of the hygroscopic material 1, the polymer resin 2 may partially surround the surface of the hygroscopic material 1 as illustrated in FIG. 4(b), or may be in the form of grains secured to the surface of the hygroscopic material 1 to form fine projections (e.g., fine projection type grains) thereon, as illustrated in FIG. 4(c).

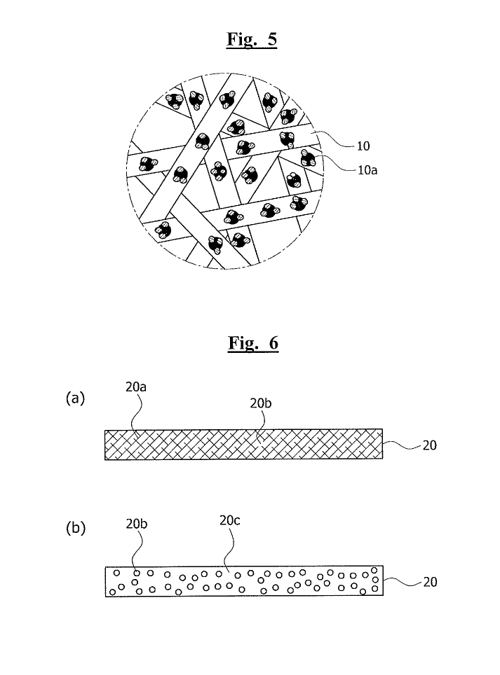

FIG. 5 illustrates a schematic view of the moisture absorption filling material to which the hygroscopic particles 10b having projections may be applied. When the polymer resin 2 is secured in the form of the fine projection type grains to the surface of the hygroscopic material 1, the fine projection type grains may be secured over an area ranging from about 0.1% to about 99.9%, about 1% to about 99%, or about 5% to about 90%, of the surface area of the hygroscopic material. Within this range of the particle distribution, the light-emitting device may be protected from the hygroscopic material without significantly deteriorating moisture absorption efficiency. In an implementation, the fine projection type grains may be secured over an area ranging from about 10% to about 80% of the surface of the hygroscopic material.

In an embodiment, the fine projection type grains may have a spherical shape, an oval shape, a semi-spherical shape, a cylindrical shape, a triangular pyramid shape, a quadrangular pyramid shape, a peanut shape, a star shape, a cluster shape, an irregular shape, or the like. In addition, the fine projection type grains may have a single particle shape or a core-shell shape.

In an embodiment, an average number of fine projection type grains discontinuously secured to the surface of the hygroscopic material may be about 1 to about 500/μm², about 5 to about 200/μm², or about 10 to about 100/μm². Within this range, the device may be protected from the hygroscopic material without significantly deteriorating moisture absorption efficiency of the hygroscopic material.

In an embodiment, the fine projection type grains may have a particle diameter of about 0.1% to about 50%, or about 0.5 to about 30%, of the particle diameter of the hygroscopic material. When the particle diameter of the fine projection type grains is within this range, the fine grains may protect the device while maintaining the shape of the particles.

In an embodiment, the fine projection type grains may have an average particle diameter ranging from about 0.005 μm to about 40 μm, about 0.05 μm to about 10 μm, about 0.01 μm to about 5 μm, or about 0.01 μm to about 1 μm. Within this range, the device may be protected from the hygroscopic material without significantly deteriorating moisture absorption efficiency of the hygroscopic material. The fine projection type grains may be smaller than the hygroscopic material 1 and may have a porosity of about 0.1% to about 50%.

The fine projection type grains may be cross-linked. The cross linking degree may range from about 0.5% to about 50%, about 1% to about 30%, or about 2% to about 20%. Within this range, the fine projection type grains formed on the surface of the hygroscopic material may have improved stability and may be securely attached to the hygroscopic material during polymerization.

The fine projection type grains may be obtained by polymerization such as, e.g., emulsion polymerization, emulsifier-free emulsion polymerization, dispersion polymerization, or the like. An exemplary method for manufacturing fine projection type grains is described in Korean Patent No. 10-0772423 and Korean Patent No. 10-0506343.

In an embodiment, the fine projection type grains may be prepared by adding a mixture (which may be obtained by dissolving an oil-soluble initiator in a vinyl monomer mixture containing a crosslinking monomer) to a solution containing a surfactant dissolved therein to prepare an aqueous emulsion, followed by adding the aqueous emulsion to a mono dispersive seed particle dispersion for swelling, and polymerizing the swollen mixture.

The fine projection type grains may be adhered to the surface of the hygroscopic material 1 by a drying method based on physical/mechanical friction, a drying method based on physical/chemical friction, wet treatment, and the like. In an embodiment, a hybridization system (obtained from Nara Machinery Co. Ltd.) may be used to secure the fine projection type grains to the surface of the hygroscopic material 1.

The weight ratio of the hygroscopic material 1 to the fine projection type grains may range from about 99:1 to about 50:50, or about 90:10 to about 60:40. Within this range, the device may be protected from the hygroscopic material without significantly deteriorating moisture absorption efficiency of the hygroscopic material.

In an embodiment, the fine projection type grains may include a functional group which provides hardness, and strong coupling and affinity to inorganic materials such as metals. Specifically, the fine projection type grains may be subjected to surface treatment using a thiol group and/or a nucleophilic functional group exhibiting metal affinity, such as a carboxyl group, a hydroxyl group, a glycol group, an aldehyde group, an oxazole group, an amine group, an amide group, an imide group, a nitro group, a nitrile group, a sulfone group, or the like.

Binder

The binder may be polyvinyl acetate (PVAc) resins, polyvinyl pyrrolidone

(PVP) resins, polyester resins such as polyethylene terephthalate resins and polybutylene terephthalate resins, polyolefin resins, (meth)acrylate resins including acrylate resins and methacrylate resins, polycarbonate resins, acrylonitrile resins, cellulose acetates, epoxy resins, phenoxy resins, siloxane resins, sulfone resins, polyamide resins, polyurethane resins, polyvinyl resins, urethane acrylate resins, fluoride resins, and the like. These materials may be used alone or in combination thereof. The binder may have a glass transition temperature ranging from about −60° C. to about 170° C., about −60° C. to about 80° C., or from about −60° C. to about 50° C. Within this range of the glass transition temperature of the binder, the moisture absorption filling material may be bonded to a sealing cap without using a bonding agent (though a bonding agent may also be used).

In an embodiment, the fibers constituting the fibrous web may include about 40 wt % to about 90 wt % of the binder and about 10 wt % to about 60 wt % of the hygroscopic particles. Within this range, the fibers may have a high moisture absorption efficiency per unit area and improved film coating properties, and may be better suited for forming the fibrous web layer.

In an embodiment, the moisture absorption filling material may further include a sheet having pores. The sheet having pores may be configured to contact at least one side of the fibrous web.

The sheet may include pores having an average diameter from about 0.1 μm to about 200 μm, about 0.5 μm to about 100 μm, or about 1 μm to about 50 μm, and may have a porosity from about 5% to about 95%, about 10% to about 80%, or about 20% to about 70%. As such, the sheet may have the pores and thus moisture and gas (such as oxygen) may smoothly pass through the sheet to react with the hygroscopic material. Further, when the sheet has a porosity within the above range, the moisture absorption filling material may have an improved moisture absorption rate. Further, the sheet having pores may have a thickness of about 0.5 μm to about 500 μm.

FIGS. 6(a) and 6(b) illustrate schematic sectional views of the sheet 20 having pores according to an embodiment. The sheet 20 may be comprised of a non-woven fabric or a woven fabric having pores 20b as shown in FIG. 6(a), or may be a porous latex sheet 20c having pores 20b as shown in FIG. 6(b).

When the sheet 20 is formed of the non-woven fabrics or the woven fabrics as shown in FIG. 6(a), fibers 20a may have an average diameter of about 0.1 μm to about 200 μm and may be regularly or irregularly entangled to provide a web structure, and pores may be formed between the fibers to provide porosity. The fibers 20a may have an average diameter from about 0.1 μm to about 200 μm, about 0.5 μm to about 100 μm, or about 0.5 μm to about 50 μm. Within this range of the average diameter of the fibers, the sheet may impart high mechanical strength to a fibrous structure and may form uniform pores to substantially prevent and/or significantly reduce deterioration in moisture absorption efficiency. In addition, the fibers may have a length ranging from about 0.1 mm to about 100 mm, about 0.5 mm to about 50 mm, or about 1 mm to about 30 mm.

The fibers forming the non-woven fabrics or the woven fabrics may be comprised of polyvinyl acetate (PVAc) resins, polyvinyl pyrrolidone (PVP) resins, polyester resins such as polyethylene terephthalate resins and polybutylene terephthalate resins, polyolefin resins, (meth)acrylate resins including acrylate resins and methacrylate resins, polycarbonate resins, acrylonitrile resins, cellulose acetates, epoxy resins, phenoxy resins, siloxane resins, sulfone resins, polyamide resins, polyurethane resins, polyvinyl resins, urethane acrylate resins, fluoride resins, and the like. These materials may be used alone or in combination thereof.

The latex sheet may be comprised of polyurethane, polybutadiene, nitrile rubber, acryl rubber, polysiloxane, and the like. These components may be used alone or in combination thereof. The latex sheet may be formed from natural or synthetic polymers.

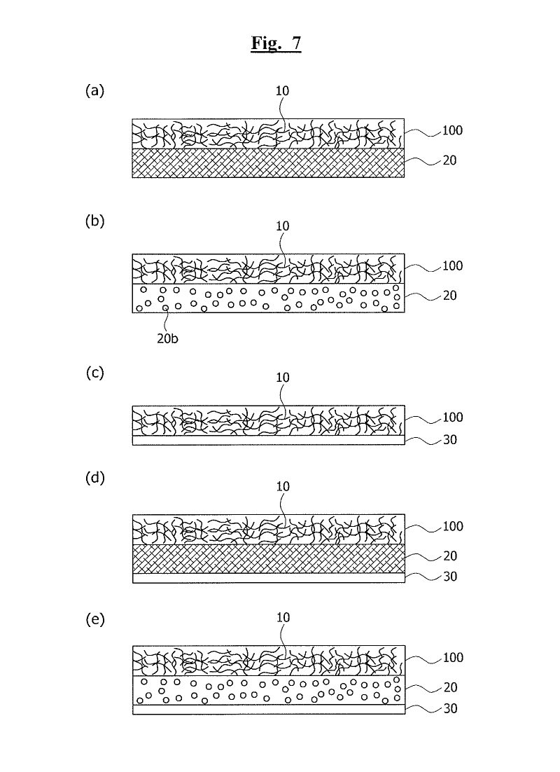

FIGS. 7(a) and 7(b) are schematic sectional view of a moisture absorption filling material for an organic light-emitting device that includes a sheet having pores, according to an embodiment. In this embodiment, the sheet 20 having pores contacts at least one side of a moisture absorption filling material 100 having a fibrous web structure.

In an embodiment, the moisture absorption filling material 100 may further include a coating layer 30 (as shown in FIG. 7(c)). The coating layer 30 may reduce average surface roughness and may have a low modulus to protect the device from impact or stress. In an embodiment, the sheet 20 having pores may be stacked on the moisture absorption filling material 100.

Although not shown in the drawings, the moisture absorption filling material 100 may be provided at both sides thereof with sheets 20 having pores. The sheets 20 having pores may be the same or different from each other. In addition, the sheets 20 having pores may be provided as a single layer or multiple layers.

In an embodiment, the sheet 20 having pores may further include a coating layer 30. For example, as shown in FIGS. 7(d) and 7(e), the moisture absorption filling material for an organic light-emitting device may include the moisture absorption filling material 100 of the fibrous web structure, the sheet 20 having pores, and the coating layer 30, which may be sequentially stacked from the bottom of the moisture absorption filler. Such a stacked structure may enhance adhesion between the sheets having pores and a substrate. Although not shown in the drawings, in an embodiment, a bonding layer may be formed between the moisture absorption filling material of the fibrous web and the sheet having pores.

In an embodiment, the coating layer may include polyvinyl acetate (PVAc) resins, polyvinyl pyrrolidone (PVP) resins, polyester resins such as polyethylene terephthalate resins and polybutylene terephthalate resins, polyolefin resins, (meth)acrylate resins including acrylate resins and methacrylate resins, polycarbonate resins, acrylonitrile resins, cellulose acetates, epoxy resins, phenoxy resins, siloxane resins, sulfone resins, polyamide resins, polyurethane resins, polyvinyl resins, urethane acrylate resins, fluoride resins, and the like. The coating layer may form a single layer or multiple layers, and in an implementation forms a single layer. Further, in an implementation, the resins may contain no residual total volatile matter (RTVM) as determined by gas chromatography, e.g., in terms of device protection.

Further, the coating layer may be a porous or non-porous layer. The coating layer may have a thickness of about 0.1 μm to about 100 μm, or about 1 μm to about 50 μm. Within this thickness range, the coating layer may protect the device from the hygroscopic material without significantly deteriorating moisture absorption efficiency.

The moisture absorption filling material for organic light-emitting devices may have a surface roughness (Ra) of greater than about 0 to about 50 μm or less, greater than about 0 to about 1 μm or less, or greater than about 0 to about 10 nm or less.

Method of preparing moisture absorption filling material for organic light-emitting device

The moisture absorption filling material including hygroscopic particles 10a secured into (e.g., embedded in) fibers of a fibrous web layer may be manufactured by, e.g., electrospinning a mixture of a binder and the hygroscopic particles. The mixture may be composed of about 40 wt % to about 90 wt % of the binder and about 10 wt % to about 60 wt % of the hygroscopic particles. Within this range, the binder may easily secure the hygroscopic particles, and stable formation of the fibrous web may be secured through adjustment of viscosity of the mixture.

In an embodiment, the mixture may further include a solvent. Examples of the solvent may include ethanol, methanol, propanol, butanol, isopropanol, acetone, methylethylketone, propylene glycol, 1-methoxy 2-propanol (PGM), isopropylcellulose (IPC), methyl cellosolve (MC), ethyl cellosolve (EC), and the like. These solvents may be used alone or in combination thereof The solvent may be present in an amount of about 100 parts by weight to about 2000 parts by weight, or about 200 parts by weight to about 1000 parts by weight, based on 100 parts by weight of the hygroscopic particles.

In an embodiment, electrospinning may be performed using the mixture of the hygroscopic particles and the binder as a spinning solution. Filaments may be spun towards a heating plate (e.g., at a lower side) by ejecting the spinning solution through a spinning nozzle while maintaining a spinning zone at a predetermined temperature range to volatize the solvent, and thus fibers may be produced from the binder including the hygroscopic particles, thereby providing a moisture absorption film having a fibrous web structure. The structure of the fibers including the fibrous web structure may be adjusted and porosity may be adjusted by adjusting the distance and/or voltage between electrodes and/or the solid content of the ejected solution. In an embodiment, the distance between the electrodes may be set in the range from about 5 cm to about 40 cm, or from about 10 cm to about 30 cm, upon electrospinning (e.g., during electrospinning). Further, electrospinning may be performed at a voltage of about 5 kV to about 45 kV, or about 15 kV to about 25 kV. Within this range of voltage upon electrospinning, a desirable fibrous web structure and porosity may be obtained.

Further, the spinning zone may be maintained at a temperature from room temperature (e.g., about 20° C.) to about 80° C., and thus the solvent from the mixture may be volatized. Within this range of temperature in the spinning zone, the fibrous web may be produced while the solvent is volatilized as soon as electrospinning is started, thereby enabling sufficient removal of the solvent from the produced fibrous web.

The moisture absorption filling material for an organic light-emitting device produced by electrospinning as described above may have a thickness from about 5 μm to about 500 μm, or about 10 μm to about 200 μm. In an embodiment, the mixture may be ejected towards at least one side of the sheet having pores by electrospinning. When the mixture is directly spun onto the sheet, the mixture may be integrated with the sheet, and thus a separate bonding process may be eliminated.

In an embodiment, the mixture may be bonded to the sheet having pores after electrospinning. In an embodiment, the mixture may be subjected to electrospinning to produce a first moisture absorption filling material and a sheet having pores may be stacked on at least one side of the first moisture absorption filling material, thereby producing a moisture absorption filling material. The sheet having pores may be attached to at least one side of the first moisture absorption filling material. In an embodiment, sheets having pores may be attached to both sides of the moisture absorption filling material. In an embodiment, first and second moisture absorption filling materials (each having the fibrous web structure) may be attached to both sides of the sheet having pores.

In an embodiment, the mixture may be directly attached to a sealing cap through electrospinning, and the sealing cap may be coupled to a substrate and may accommodate an organic electroluminescent unit. In this case, there may not be a need for a separate attachment process between the sealing cap and the moisture absorption filling material (though a separate attachment process may also be used).

Organic Light-Emitting Device

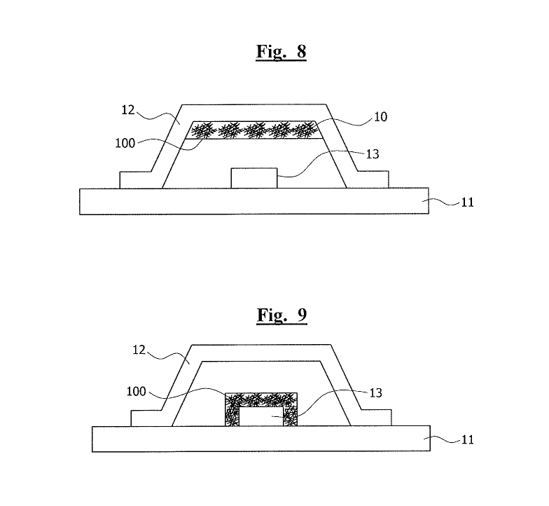

In an embodiment, an organic light-emitting device may include the moisture absorption filling material. FIG. 8 illustrates a sectional view of an organic light-emitting device according to an embodiment. The organic light-emitting device may include a substrate 11, an organic electroluminescent unit 13 formed on one side of the substrate and including a first electrode, an organic light emitting layer, and a second electrode, a sealing cap 12 coupled to the substrate and accommodating the organic electroluminescent unit therein, and a drying mechanism disposed inside the sealing cap. As the drying mechanism, the moisture absorption filling material 100 for organic light-emitting devices may be used.

Although the moisture absorption filling material 100 is illustrated as being secured to a certain location of the sealing cap 12 in FIG. 8, the location of the absorption filling material 100 may be a suitable location (e.g., a location other than the location illustrated in FIG. 8). In an embodiment, the moisture absorption filling material 100 may be secured to at least part of the sealing cap 12. In an embodiment, the moisture absorption filling material 100 may be interposed between the organic electroluminescent unit 13 and the sealing cap 12.

The hygroscopic filler 100 for organic light-emitting devices may be secured to the sealing cap 12 by bonding or the like. In this case, the organic light-emitting device may be separated a certain distance from the moisture absorption filling material such that a space therebetween may be filled with inert gas. In an embodiment, the hygroscopic filler 100 may be secured to the sealing cap 12 by directly electrospinning to the sealing cap 12 without using media such as adhesives.

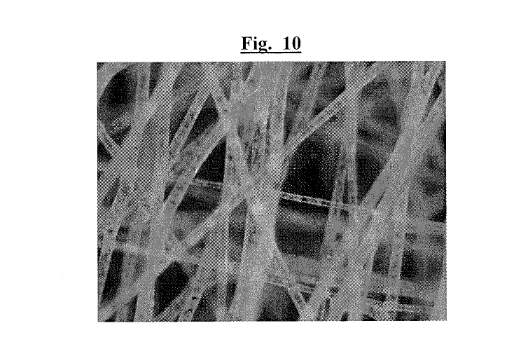

In an embodiment, the moisture absorption filling material 100 may directly contact the organic electroluminescent unit 13. FIG. 9 illustrates a schematic sectional view of the organic EL device according to this embodiment. Alternatively, the moisture absorption filling material 100 may contact the organic electroluminescent unit 13 while filling the sealing cap 12.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLE 1

A mixture of 70 parts by weight of an acrylic resin (in terms of solid content) (Cheil Industries Inc.) mainly composed of butyl acrylate and having low glass transition temperature and 30 parts by weight of metal oxide (CaO) particles as hygroscopic particles was dissolved in 100 parts by weight of methylethylketone as a solvent, thereby preparing a spinning solution. The spinning solution was subjected to electrospinning using an electrospinning device at 5 kV to prepare a 50 μm thick moisture absorption filling material for organic light-emitting devices. To measure fiber diameter and porosity, the prepared moisture absorption filling material was photographed using an optical microscope, and FIG. 10 is an optical microscopic image of the moisture absorption filling material. The measurement results showed that the moisture absorption filling material had an average fiber diameter of 30 μm and a porosity of 50%.

The prepared moisture absorption filling material was secured to a sealing cap. Separately, an organic electroluminescent unit, including a glass substrate, a first electrode, an organic light emitting layer, and a second electrode, was prepared and placed in the sealing cap to which the organic electroluminescent unit was secured, followed by sealing the sealing cap on the substrate, thereby providing an organic light-emitting device.

### EXAMPLE 2

The organic light-emitting device was prepared in the same manner as in Example 1 except that electrospinning was carried out at a voltage of 10 kV.

### EXAMPLE 3

The organic light-emitting device was prepared in the same manner as in Example 1 except that electrospinning was carried out at a voltage of 15 kV.

### EXAMPLE 4

The organic light-emitting device was prepared in the same manner as in Example 1 except that electrospinning was carried out at a voltage of 20 kV.

### EXAMPLE 5

The organic light-emitting device was prepared in the same manner as in Example 3 except that urethane acrylate (Cheil Industries Inc.) mainly composed of a polyol and multi-isocyanate was used as a binder.

### EXAMPLE 6

The organic light-emitting device was prepared in the same manner as in

Example 3 except that a fluoride resin (Solef 1008, Solvay Co., Ltd.) was used as a binder.

### COMPARATIVE EXAMPLE 1

The organic light-emitting device was prepared in the same manner as in Example 1 except that a 50 μm thick moisture absorption filling material was prepared by casting the mixture of Example 1 under drying conditions at 80° C.

### COMPARATIVE EXAMPLE 2

The organic light-emitting device was prepared in the same manner as in Example 5 except that a 50 μm thick moisture absorption filling material was prepared by casting the mixture of Example 5 under drying conditions at 80° C.

The organic light-emitting device was prepared in the same manner as in Example 6 except that a 50 μm thick moisture absorption filling material was prepared by casting the mixture of Example 6 under drying conditions at 150° C.

TABLE 1

| | | 30% of | | |
|---|---|---|---|---|
| | | hygroscopic | | |
| | 70% of binder | particles | Film preparation method | |
| Example 1 | Acrylic resin | CaO | Electrospinning | 5 kV |
| Example 2 | Acrylic resin | CaO | Electrospinning | 10 kV |
| Example 3 | Acrylic resin | CaO | Electrospinning | 15 kV |
| Example 4 | Acrylic resin | CaO | Electrospinning | 20 kV |
| Example 5 | Urethane | CaO | Electrospinning | 15 kV |
| | acrylic resin | | | |
| Example 6 | Fluoride resin | CaO | Electrospinning | 15 kV |
| Comparative | Acrylic resin | CaO | Solvent casting | drying at |
| Example 1 | | | | 80° C. |
| Comparative | Urethane | CaO | Solvent casting | drying at |
| Example 2 | acrylic resin | | | 80° C. |
| Comparative | Fluoride resin | CaO | Solvent casting | drying at |
| Example 3 | | | | 150° C. |

The organic light-emitting devices prepared in Examples 1 to 6 and Comparative Examples 1 to 3 were evaluated as to moisture absorption efficiency and tack by the following methods, and results are shown in Table 2.

1. Moisture absorption efficiency: Maximum moisture absorption efficiency was evaluated according to weight increase after 200 hours under moisture absorption conditions of 85° C. and 85%.

2. Tack: Tack was defined as a capability of being adhered to an adherend under a very slight load in a short time and evaluated by ball tack. Ball speed was 0.08 mm/sec.

3. Surface roughness (Ra): A non-contact type surface roughness tester NV6300 (ZYGO Co., Ltd.) was used to measure surface roughness.

TABLE 2

| | Average | | | | |
|---|---|---|---|---|---|
| | fiber | | Moisture | | Surface |
| | diameter | Porosity | absorption | Tack | roughness |
| | (μm) | (%) | efficiency (%) | [gF] | (μm) |
| Example 1 | 30 | 50 | 13 | 307 | 15 |
| Example 2 | 20 | 45 | 13 | 295 | 8 |
| Example 3 | 15 | 40 | 15 | 290 | 6 |
| Example 4 | 13 | 40 | 15 | 292 | 5 |
| Example 5 | 15 | 40 | 16 | 62 | 5 |
| Example 6 | 13 | 40 | 14 | 5 | 4 |
| Comparative | — | 0 | 12 | 311 | 0.1 |
| Example 1 | | | | | |
| Comparative | — | 0 | 13 | 65 | 0.2 |
| Example 2 | | | | | |
| Comparative | — | 0 | 10 | 4 | 0.1 |
| Example 3 | | | | | |

As shown in Table 2, it could be seen that the moisture absorption filling material prepared through electrospinning had excellent moisture absorption efficiency and rate, and exhibited similar tack characteristics to those of a film type. Furthermore, the moisture absorption filling material exhibited superior moisture absorption efficiency to Comparative Examples 1 to 3.

By way of summary and review, an organic light-emitting device may have a problem in that an organic layer and a metal layer of the organic light-emitting device may be gradually oxidized (e.g., due to moisture infiltration or generation of oxygen, carbon monoxide, moisture, and the like) in the course of operation for a certain period of time, thereby significantly deteriorating luminescent characteristics such as, e.g., brightness, luminescence uniformity, and the like. Specifically, a luminescent substance may be converted into a non-luminescent polymer through reaction with moisture, and thus dark spots may be formed, which may result in deterioration in luminous efficacy while increasing device impedance due to low charge transport capability. Further, oxidation of the metal layer (e.g., used for a cathode) may results in flaking of the metal layer from the organic layer which may cause rapid deterioration in electron injection efficiency, whereby the lifespan of the device may be gradually shortened. As such, the organic light-emitting device may be vulnerable to moisture and oxygen, and thus the organic light-emitting device may be provided therein with a getter including a drying mechanism capable of absorbing moisture in an encapsulation process for reducing (e.g., blocking) moisture and oxygen.

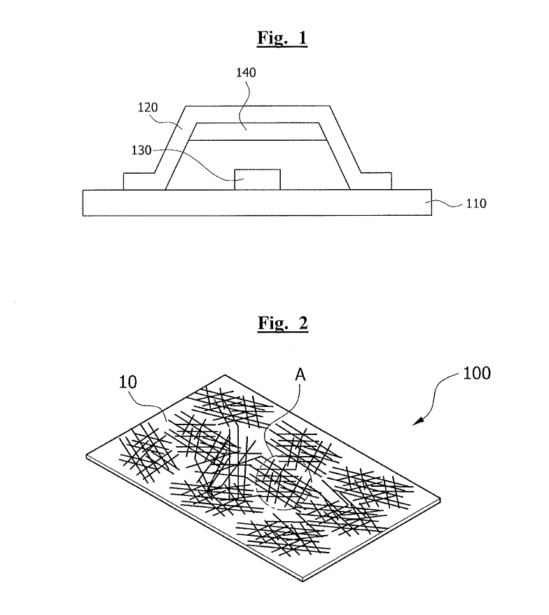

FIG. 1 illustrates a schematic sectional view of an exemplary sealing structure of an organic light-emitting device on which a getter is mounted. As shown in this figure, an organic light-emitting device may include a substrate 110, an organic electroluminescent unit 130 formed on one side of the substrate 110, and a sealing cap 120 coupled to the substrate and accommodating the organic electroluminescent unit therein. A drying mechanism 140 for absorbing moisture may be formed on at least part of the sealing cap 120.

The drying mechanism may be in the form of a sealed moisture permeable pocket receiving a hygroscopic powder (such as calcium oxide (CaO) powder), pellets formed by compressing the hygroscopic powders, or a film formed by mixing the hygroscopic powders with a polymer binder. The pocket type may be thicker than the film type drying mechanism and may have problems such as pocket swelling and powder falling on the device at high temperature. In addition, the pellet type drying mechanism may have difficulty producing a thin layer and low durability. A film type getter may be produced by mixing inorganic fillers and a polymer binder. Such a film type drying mechanism may have a simple configuration and may be advantageously manufactured into a thin layer having a thickness of several micrometers or less. However, this film type may have disadvantages such as significant separation of powders from the getter and significantly low moisture absorption rate due to the polymer binder film.

In addition, although silicon oil may be used, it may be difficult to reach a practical level applicable to an OLED even after dehydration of the silicon oil for a long period of time. Moreover, addition of the silicon oil may require a structure for injecting the liquid into the device and thus may complicate the process.

The moisture absorption filling material for an organic light-emitting device according to the embodiments, which may include hygroscopic particles secured in fibers, may not generate dark spots, may exhibit excellent properties in terms of moisture absorption efficiency, moisture absorption rate, holding force with respect to a hygroscopic material, filling capability, workability, and ease of fabrication, and may substantially prevent and/or significantly reduce damage of component films. The moisture absorption filling material for an organic light-emitting device according to the embodiments may also allow for easy adjustment of thickness. Thus, the moisture absorption filling material may be advantageously used for manufacturing organic light-emitting devices having improved luminescent characteristics and lifespan.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims

What is claimed is:

1. A moisture absorption filling material for an organic light-emitting device, the material comprising:
a fibrous web structure including an assembly of fibers, the fibers including a binder resin and hygroscopic particles, the hygroscopic particles being secured into the fibers.

2. The moisture absorption filling material as claimed in claim 1, wherein the fibers have an average diameter of about 0.1 μm to about 200 μm.

3. The moisture absorption filling material as claimed in claim 1, wherein the moisture absorption filling material has a porosity of about 5% to about 95% and is formed with pores having an average diameter of about 0.1 μm to about 100 μm.

4. The moisture absorption filling material as claimed in claim 1, wherein the hygroscopic particles include:
a hygroscopic material particle made of a hygroscopic material,
a surface-treated hygroscopic material particle obtained by surface treatment of the hygroscopic material with a polymer resin, or
a mixture of the hygroscopic material particle and the surface-treated hygroscopic material particle.

5. The moisture absorption filling material as claimed in claim 4, wherein the hygroscopic material includes at least one selected from the group of a molecular sieve zeolite, a silica gel, a carbonate, a clay, a metal oxide, a metal hydroxide, an alkali earth metal oxide, a sulfate, a metal halide, a perchlorate, an organic metal compound, and an organic/inorganic hybrid material that physically or chemically adsorbs moisture.

6. The moisture absorption filling material as claimed in claim 4, wherein:
the hygroscopic particles include the surface-treated hygroscopic material particle obtained by surface treatment of the hygroscopic material with the polymer resin, and
the polymer resin is continuously or discontinuously secured to a surface of the hygroscopic material.

7. The moisture absorption filling material as claimed in claim 6, wherein the polymer resin is secured to the surface of the hygroscopic material in a ratio of about 5% to about 100% of a surface area of the hygroscopic material.

8. The moisture absorption filling material as claimed in claim 6, wherein the polymer resin is secured to the surface of the hygroscopic material by forming a polymer resin coating layer on the hygroscopic material, or by disposing fine projection type polymer resin grains on the hygroscopic material.

9. The moisture absorption filling material as claimed in claim 4, wherein the hygroscopic material has an average particle diameter ranging from about 0.01 μm to about 200 μm.

10. The moisture absorption filling material as claimed in claim 1, wherein the binder includes at least one selected from the group of a polyvinyl acetate resin, a polyvinyl pyrrolidone resin, a polyester resin, a polyolefin resin, a (meth)acrylate resin, a polycarbonate resin, an acrylonitrile resin, a cellulose acetate resin, an epoxy resin, a phenoxy resin, a siloxane resin, a sulfone resin, a polyamide resin, a polyurethane resin, a polyvinyl resin, a urethane acrylate resin, and a fluoride resin.

11. The moisture absorption filling material as claimed in claim 1, wherein the binder has a glass transition temperature of about −60° C. to about 170° C.

12. The moisture absorption filling material as claimed in claim 1, wherein the binder has a glass transition temperature of about −60° C. to about 80° C.

13. The moisture absorption filling material as claimed in claim 1, wherein the fibers include about 40 wt % to about 90 wt % of the binder and about 10 wt % to about 60 wt % of the hygroscopic particles.

14. The moisture absorption filling material as claimed in claim 1, wherein the moisture absorption filling material has a thickness of about 5 μm to about 500 μm.

15. The moisture absorption filling material as claimed in claim 1, further comprising a coating layer.

16. The moisture absorption filling material as claimed in claim 1, further comprising:
a sheet having pores, the sheet contacting at least one side of the fibrous web structure.

17. The moisture absorption filling material as claimed in claim 16, wherein the sheet has a porosity of about 5% to about 95%.

18. The moisture absorption filling material as claimed in claim 16, wherein the sheet is a moisture permeable sheet, and includes a non-woven fabric, a woven fabric, a latex sheet, or a combination thereof.

19. The moisture absorption filling material as claimed in claim 18, wherein:
the non-woven fabric includes at least one selected from the group of a polyvinyl acetate resin, a polyvinyl pyrrolidone resin, a polyester resin, a polyolefin resin, a (meth)acrylate resin, a polycarbonate resin, an acrylonitrile resin, a cellulose acetate resin, an epoxy resin, a phenoxy resin, a siloxane resin, a sulfone resin, a polyamide resin, a polyurethane resin, a polyvinyl resin, a urethane acrylate resin, and a fluoride resin,
the woven fabric includes at least one selected from the group of a polyvinyl acetate resin, a polyvinyl pyrrolidone resin, a polyester resin, a polyolefin resin, a (meth)acrylate resin, a polycarbonate resin, an acrylonitrile resin, a cellulose acetate resin, an epoxy resin, a phenoxy resin, a siloxane resin, a sulfone resin, a polyamide resin, a polyurethane resin, a polyvinyl resin, a urethane acrylate resin, and a fluoride resin, and
the latex sheet includes at least one selected from the group of a polyurethane, a polybutadiene, a nitrile rubber, an acryl rubber, and a polysiloxane.

20. The moisture absorption filling material as claimed in claim 16, wherein the sheet has a thickness of about 0.5 μm to about 500 μm.

21. The moisture absorption filling material as claimed in claim 16, wherein the sheet includes a coating layer formed thereon.

22. The moisture absorption filling material as claimed in claim 21, wherein the moisture absorption filling material has a structure in which the fibrous web structure, the sheet having pores, and the coating layer are sequentially stacked.

23. The moisture absorption filling material as claimed in claim 16, wherein the moisture absorption filling material has a surface roughness (Ra) of about 50 μm or less.

24. A method of preparing a moisture absorption filling material for an organic light-emitting device, the method comprising:
electrospinning a mixture including about 10 wt % to about 60 wt % of hygroscopic particles and about 40 wt % to about 90 wt % of a binder.

25. The method as claimed in claim 24, wherein the mixture further includes a solvent.

26. The method as claimed in claim 24, wherein the mixture is applied to at least one side of a sheet having pores by electrospinning.

27. The method as claimed in claim 24, wherein the mixture is directly applied to a sealing cap by electrospinning, and the sealing cap is coupled to a substrate and accommodates an organic electroluminescent unit.

28. The method as claimed in claim 24, further comprising:
preparing a moisture absorption filling material by electrospinning the mixture; and
stacking a sheet having pores on at least one side of the moisture absorption filling material.

29. The method as claimed in claim 28, wherein the sheet is adhesively attached to the at least one side of the moisture absorption filling material.

30. The method as claimed in claim 24, wherein the electrospinning is performed at an interelectrode distance of about 5 cm to about 40 cm and at a voltage of about 5 kV to about 45 kV.

31. The method as claimed in claim 24, wherein, upon the electrospinning, an electrospinning zone is maintained at a temperature ranging from room temperature to about 80° C.

32. An organic light-emitting device comprising the moisture absorption filling material as claimed in claim 1.

33. An organic light-emitting device, comprising:
a substrate;
an organic electroluminescent unit on one side of the substrate, the organic electroluminescent unit including a first electrode, an organic light emitting layer, and a second electrode;
a sealing cap coupled to the substrate and accommodating the organic electroluminescent unit therein; and
a drying mechanism within the sealing cap, the drying mechanism being the moisture absorption filling material as claimed in claim 1.
